(19) United States
(12) Patent Application Publication
(10) Pub. No.: US 2015/0048509 A1
(43) Pub. Date: Feb. 19, 2015

(54) CMOS COMPATIBLE WAFER BONDING LAYER AND PROCESS

(71) Applicant: GLOBALFOUNDRIES Singapore Pte. Ltd., Singapore (SG)

(72) Inventors: Ranganathan NAGARAJAN, Singapore (SG); Fu Chuen TAN, Singapore (SG); Kia Hwee Samuel LOW, Singapore (SG); Chun Hoe YIK, Singapore (SG); Jiaqi WU, Singapore (SG); Jingze TIAN, Singapore (SG); Pradeep Ramachandramurthy YELEHANKA, Singapore (SG); Rakesh KUMAR, Singapore (SG)

(21) Appl. No.: 14/459,329

(22) Filed: Aug. 14, 2014

Related U.S. Application Data
(60) Provisional application No. 61/866,549, filed on Aug. 16, 2013.

(51) Int. Cl. H01L 21/18; H01L 21/3205; H01L 23/482

(52) U.S. Cl. CPC H01L 21/185; H01L 23/4827; H01L 21/32051; H01L 21/32055
USPC 257/751; 438/455

(57) ABSTRACT

A wafer bonding layer and a process for using the same for bonding wafers are presented. The wafer bonding process includes providing a first wafer, providing a second type wafer and providing a water bonding layer. The wafer bonding layer is provided separately on a contact surface layer of the first or second wafer as part of a CMOS compatible processing recipe.

### CROSS-REFERENCE TO RELATED APPLICATION

This application claims the priority benefit of U.S. Provisional Application Ser. No. 61/866,549, filed on Aug. 16, 2013, which is herein incorporated by reference in its entirety.

### BACKGROUND

Recent innovations in three-dimensional (3D) chip, die and wafer integration (hereinafter, collectively, stacked structures) have enabled a greater miniaturization of devices as well as technological advancements in increased speed and density, with reduced power consumption and cost. Wafer bonding relates to packaging technology on a wafer-level which allows for vertical stacking of two or more wafers and to provide electrical connection and hermetical sealing between the waters.

Various wafer bonding techniques have been developed and employed to join two wafers of the same or different types. However, conventional bonding techniques are not flexible and cannot be extended to various forms of heterogeneous device integration nor can it be used for bonding non-silicon types of surfaces. Furthermore, there is also a growing demand in the industry for packaging processes where a first type wafer, such as a CMOS wafer, can be bonded to a second type wafer, such as MEMS wafer, using CMOS foundry compatible materials.

From the foregoing discussion, it is desirable to provide a bonding methodology which is CMOS compatible and which can be used to bond wafers of the same or different types. It is also desirable to provide a wafer bonding process that is flexible and provides hermetic sealing and electrical connection.

### SUMMARY

Embodiments generally relate to wafer bonding layers and processes for using the same for bonding wafers.

In one embodiment, the wafer bonding layer includes a Ge layer and a barrier layer. The Ge layer is disposed on the barrier layer. In one embodiment, the Ge layer is a single barrier layer. In another embodiment, the Ge layer is a Ge/Al multilayer that includes a series of thinner Ge layers that is interspersed in an alternating manner with a series of thinner Al layers. The barrier layer may be an electrical conductor or an electrical insulator layer.

In one embodiment, the wafer bonding process includes providing a first wafer, providing a second wafer and providing a wafer bonding layer. The wafer bonding layer is formed separately on a contact surface layer of the first or second wafer as part of a CMOS compatible processing recipe.

In another embodiment, the wafer bonding process includes providing a first wafer, providing a second wafer and providing a wafer bonding layer. The wafer bonding layer is formed separately on a contact surface layer of the first or second wafer as part of a CMOS compatible processing recipe and the contact surface layer of the other wafer is an Aluminum layer.

These and other advantages and features of the embodiments herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. Various embodiments of the invention are described with reference to the following drawings, in which:

FIGS. 1a-1c show various embodiments of a wafer assembly;

FIGS. 2a-2d show cross-section views of embodiments of a wafer bonding layer in a eutectic bonding process; and

FIGS. 3a-3d show cross-section views of other embodiments of a wafer bonding layer in a eutectic bonding process.

### DETAILED DESCRIPTION

Embodiments generally relate to wafer bonding methodologies that allow for bonding of two or more of the same or different types of wafers using a separate CMOS foundry compatible material which forms eutectic bond with contact surface layer of the wafer. In some of the embodiments, the wafer bonding layers and processes allow for bonding of two or more of the same or different types of wafers as tong as one of the top/contact surfaces of the wafers is an Aluminum layer. The wafer bonding layers and processes as will be described below are compatible between MEMS and CMOS. For example, some embodiments relate to CMOS wafers that can be vertically integrated to improve performance of MEMS device as demands grow for added functionality, smaller size and higher gross dies per wafer. Furthermore, such wafer bonding process should also be low cost without the need to use expensive bonding materials such as Au—Sn or Ag—Sn.

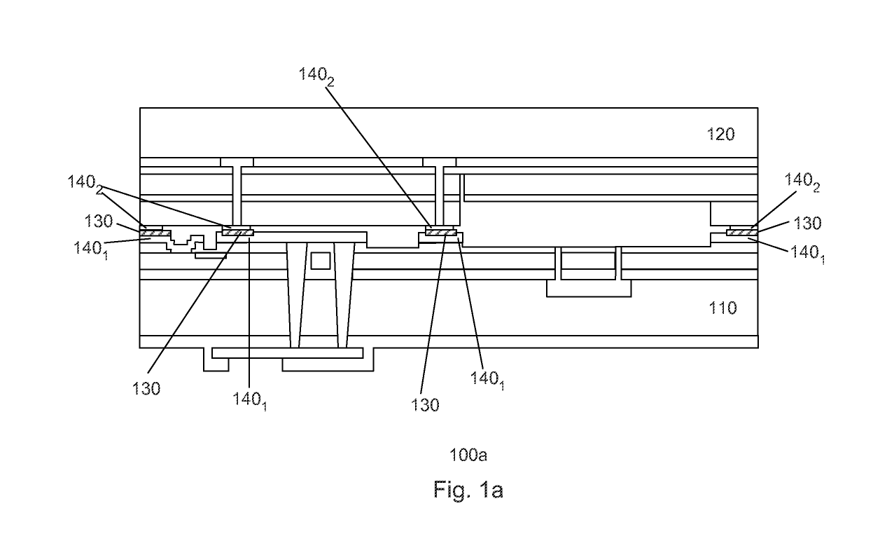

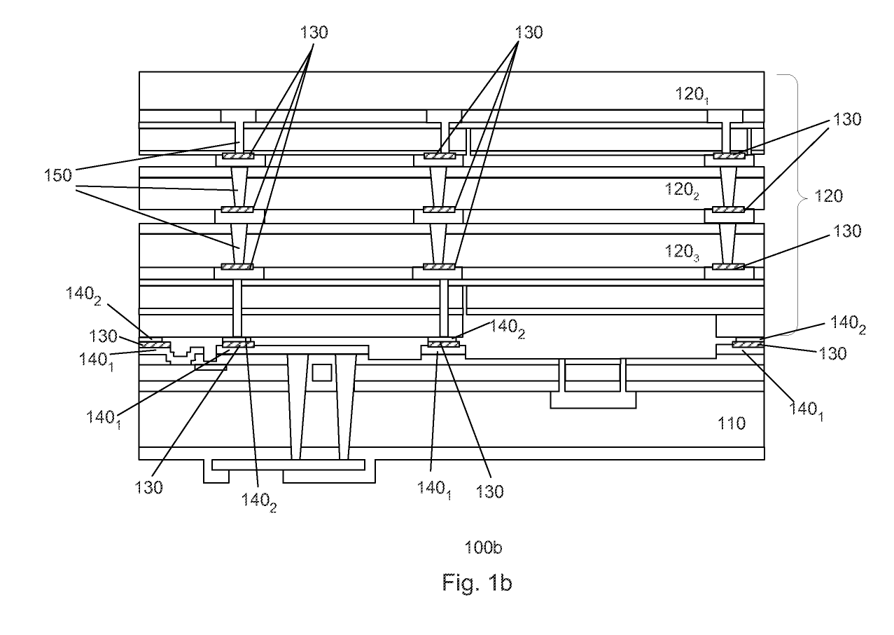

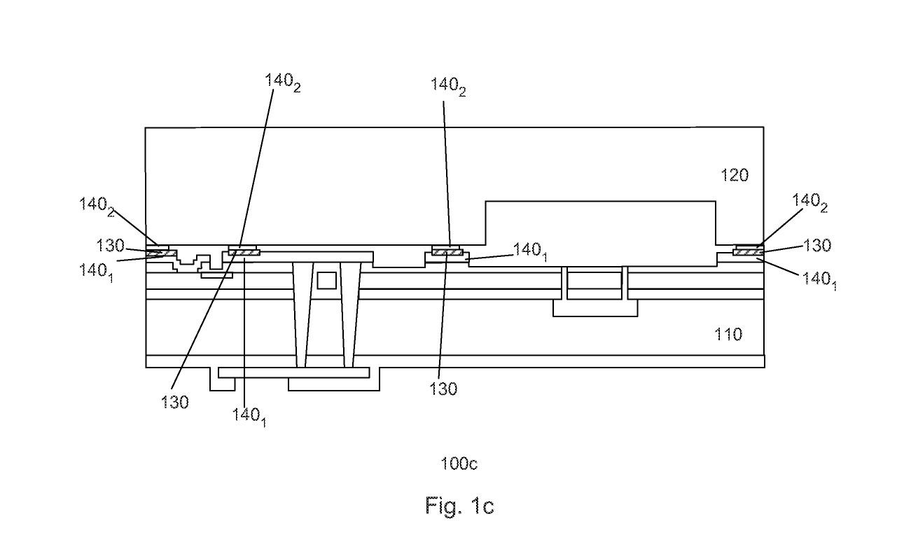

FIGS. 1a-1c show various embodiments of a wafer level assembly. Referring to FIG. 1a, a first wafer 110 is bonded with a second wafer 120, forming a wafer assembly 100a. The first and second wafers, in one embodiment, are different types of wafer. In one embodiment, the first wafer 110 is a MEMS wafer while the second wafer 120 is a CMOS cap wafer. Other suitable types of wafers may also be useful. In other embodiments, the first and second wafers are of the same type. The first wafer 110 is bonded with the second wafer 120 by a wafer bonding layer 130 between first and second contact surface layers 140₁ and 140₂. The first contact surface layer 140₁ is disposed on the surface of the first wafer 110 and the second contact surface layer 140₂ is disposed on the surface of the second wafer 120.

The first contact surface layer 140₁, for example, may be the top most conductive or metal layer of the first wafer 110 while the second contact surface layer 140₂, for example, may be the top most conductive or metal layer of the second wafer 120. For instance, if the second wafer 120 is a CMOS cap wafer, the second contact surface layer 140₂ may be the top most metal layer or contact pad of the CMOS wafer and if the first wafer 110 is a MEMS wafer, the first contact surface layer 140₁ may be the top most conductive or metal layer of the MEMS wafer, which is properly patterned to match the corresponding second contact surface layer 140₂ of the CMOS cap wafer. The bonding of the first contact surface layer 140₁ of the first wafer to the second contact surface layer 140₂ of the second wafer is facilitated by providing a wafer bonding layer 130 which is non-native to the first or second wafers. For example, the wafer bonding layer is provided separately and is not part of the contact surface layer or metallization layer of the first or second wafer.

FIG. 1b shows another embodiment of a wafer assembly 100b which is similar to the wafer assembly 100a shown in FIG. 1a. Common elements will not be described or described in detail. The wafer assembly 100b shows a first type wafer 110 that is bonded with a second type wafer 120 by a wafer bonding layer 130. The first type wafer, for example, includes a MEMS wafer, while the second type wafer 120, for example, includes a multilayer CMOS cap wafer 120, forming a three-dimensional (3D) integrated circuit. For illustration purpose, there are three CMOS wafers (120₁, 120₂ and 120₃) within the multilayer CMOS cap wafer 120.

However, it should be understood that the multilayer CMOS cap wafer 120 may include two or more CMOS cap wafers. Adjacent CMOS wafers of the plurality of CMOS wafers are bonded together by the use of wafer bonding layer 130 and interconnected by through silicon vias 150. As shown, wafer bonding layer 130 may also be used for bonding wafers that are of the same type. While FIG. 1b shows CMOS cap wafers bonded together by the use of wafer bonding layer 130, it should be understood that the wafer bonding layer 130 could also be used for bonding two or more MEMS wafers together. In other embodiments, wafer bonding layer 130 may be used for bonding other same types of wafers together.

FIG. 1c shows another embodiment of a wafer assembly 100c which is similar to wafer assembly 100a shown in FIG. 1a. As such, common elements will not be described or described in detail. Similar to FIG. 1a, a first wafer 110 is bonded with a second wafer 120 by a wafer bonding layer 130 as shown in FIG. 1c. In one embodiment, the first wafer 110 is a MEMS wafer while the second wafer 120 is a dummy cap wafer. The MEMS wafer 110, as shown, is bonded with the dummy cap wafer 120 by a wafer bonding layer 130. The dummy cap wafer 120 includes a semiconductor substrate, such as silicon substrate, which has no device embedded within. As such, it is used only for hermetic bonding with MEMS wafer 110 as there are no electrical connections between the MEMS wafer 110 and the dummy cap wafer 120. Notwithstanding the foregoing, electrical contacts may at times exist within the dummy cap wafer to ground the dummy cap wafer so the dummy cap wafer can serve as a shield.

As described in all of the wafer assemblies above, the first wafer is bonded with the second wafer by wafer bonding layer 130. In one embodiment, one of the contact surface layers 140 is an Aluminum layer and the wafer bonding layer 130 may be used to bond the first wafer with the second wafer. As described, the first and second wafers may be of the same or different type. The wafer bonding layer 130, in one embodiment, facilitates or enables bonding with an Aluminum contact surface layer on one of the first and second wafers regardless of what type of material the contact surface layer of the other wafer is. As such, in one embodiment, only one of the two wafers to be bonded together; be it the first wafer or the second wafer needs to have an Aluminum contact surface layer. Notwithstanding the foregoing, the wafer bonding layer 130 may also be used when both the first and second wafers have an Aluminum contact surface layer.

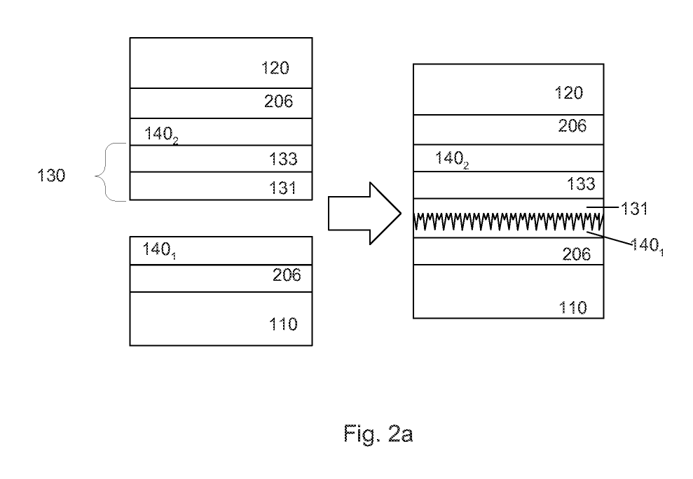

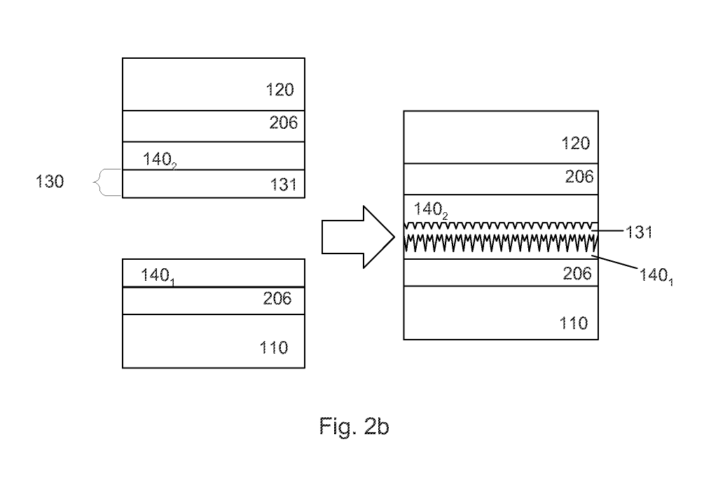

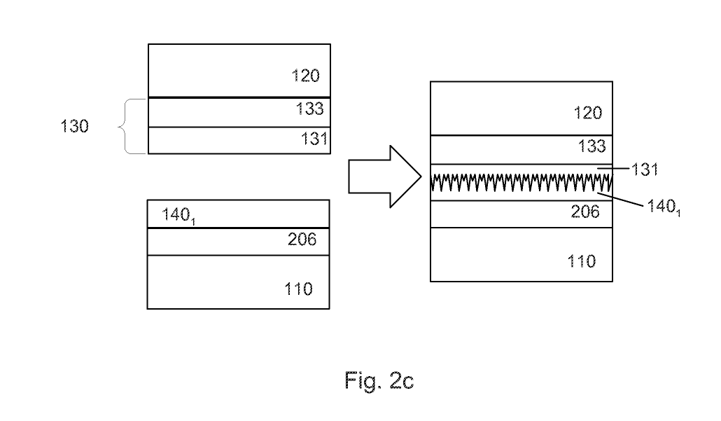

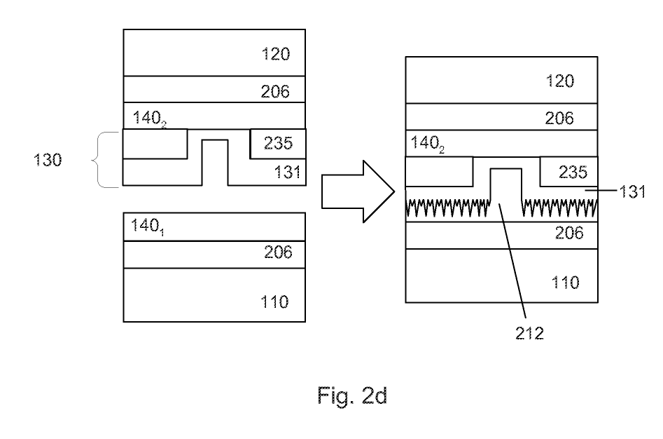

FIGS. 2a-2d show cross-section views of embodiments of the wafer bonding layer 130 in a eutectic bonding process which may be applied in any of the wafer assemblies as described in FIGS. 1a-1c. Referring to FIG. 2a, which shows the use of a wafer bonding layer 130 in a bonding process that requires a lot of electrical connections to be made between the wafers to be bonded. As shown on the left side of the FIG. 2a, first and second wafers 110 and 120 are provided. The first and second waters 110 and 120 each having a dielectric layer 206 formed in between the wafers 110 and 120 and contact surface layers 140₁ and 140₂, respectively. In one embodiment, the first wafer is a first type wafer and the second wafer is a second type wafer of which the first and second types are different. For example, the first and second type wafers 110 and 120 include a MEMS wafer and a CMOS wafer, but other suitable wafer combinations may also be useful. Alternatively, the first and second type wafers can be of the same type. The first and second contact surface layers 140₁ and 140₂, for example, include Aluminum layer.

The wafer bonding layer 130 is non-native to the first or second wafer. For example, the wafer bonding layer is provided separately and is not part of the contact surface layer or metallization layer of the first or second wafer. The wafer bonding layer may be deposited as a separate layer on either wafer 110 or wafer 120. Wafer bonding layer 130 may be deposited on, for example, any one of the surfaces of wafer 110/120 which are facing each other. In one embodiment, the wafer bonding layer 130 includes a bonding layer 131 and a barrier layer 133. The bonding layer 131, for example, includes a CMOS foundry compatible material which can form a eutectic bond with the contact surface layer which includes, for example, Aluminum. In one embodiment, the bonding layer 131 includes a Ge layer. The Ge layer is deposited on the barrier layer 133, forming the wafer bonding layer 130. Other suitable metallic materials which are CMOS foundry compatible and form eutectic bond with the contact surface material may also be used as the bonding layer. In this embodiment, barrier layer 133 is a diffusion barrier layer and includes a conductive material. The inclusion of barrier layer 133 in wafer bonding layer 130 provides a diffusion barrier layer between, for example, the Ge layer 131 of wafer bonding layer 130 and the Aluminum layer 140 on either wafer 110 or 120, depending on which wafer bonding layer 130 is deposited on, to prevent excessive inter-diffusion and squeeze out due to molten AlGe during the eutectic bonding process.

The barrier layer, in one embodiment, includes Ti, TiN, Ta, TaN or any other alloy thereof. Other suitable types of diffusion barrier layer may also be useful, depending on, for example, the material of the bonding layer and the adhesion properties and etch characteristics of the barrier layer. As shown in FIG. 2a, the wafer bonding layer 130 is formed on the Aluminum layer 140₂ of wafer 120. Alternatively, the wafer bonding layer is provided on the Aluminum layer 140₁ of wafer 110. If the wafer bonding layer is provided on the Aluminum layer 140₁ of wafer 110, the barrier layer 133 of the wafer bonding layer 130 will be disposed directly on the Aluminum layer 140₁. The use of wafer bonding layer 130 provides more flexibility as it allows bonding between any two wafer surfaces as long as one of the wafer surface has an Aluminum contact surface layer and such bonding is possible regardless of which wafer surface has the Aluminum contact surface layer. In the case where the first and second wafers are active wafers, the wafer bonding layer also provides electrical connection between the first and second active wafers as the wafer bonding layer includes the bonding and barrier layers which are both conductive.

The right side of FIG. 2a shows wafer bonding layer 130 following the formation of a eutectic bond between wafer 110 and wafer 120. As can be seen, the Ge layer 131 of wafer bonding layer 130 facilities bonding with the Aluminum layer 140₁ of wafer 110, while the barrier layer 133 of wafer bonding layer 130 protects the Aluminum layer 140₂ of wafer 120 from reacting with the Ge layer 131 of wafer bonding layer 130. This process is therefore very stable and does not require much control during the eutectic bonding process.

FIG. 2b shows an alternative embodiment, in which the wafer bonding layer 130 includes a single bonding layer 131, such as a Ge layer, but wafers 110 and 120 have the same layers as that shown in FIG. 2a. As such, common elements may not be described or described in detail As shown in FIG. 2b, wafer bonding layer 130 is formed on the Aluminum layer 140₂ of wafer 120. It is understood that the wafer bonding layer 130 may be formed on the Aluminum layer 140₁ of wafer 110 instead of on the Aluminum layer 140₂ of wafer 120. In this embodiment, given that the wafer bonding layer 130 includes a single Ge layer 131; the eutectic bonding process have to be controlled very carefully to ensure that the bonding time is not too long, the Ge layer 131 is sufficiently thick and will not be depleted and the Aluminum layer 140 on both wafers 110 and 120 is sufficiently thick to ensure even diffusion of the Ge layer 131 into the Aluminum layers 140 of wafers 110 and 120. The use of a single Ge layer 131 as the bonding layer simplifies the process and is suitable when the design is more relaxed to accommodate greater inter-diffusion between the Ge layer 131 and the Aluminum layer 140 on both wafers 110 and 120.

FIG. 2c shows yet another embodiment of the wafer bonding layer 130 in a eutectic bonding process which is similar to that described in FIGS. 2a and 2b. As such, common elements may not be described or described in detail. Referring to FIG. 2c, the wafer bonding layer 130 includes a bonding layer 131 and a barrier layer 133. The bonding layer 131 and the barrier layer 133 are the same as that described in FIG. 2a. This embodiment shows a bonding process where not many electrical connections are made between the two wafers being bonded together. As such, while wafer 110 has the same layers as that shown in FIG. 2a, wafer 120 may include only the wafer substrate layer. The wafer substrate preferably includes silicon. Other suitable types of materials, such as but not limited to glass, silicon-on-insulator (SOI), GaAs or GaN, may also be useful. In this case, the wafer bonding layer 130 may be directly deposited on the wafer substrate surface of wafer 120 as the diffusion barrier layer 133 in wafer bonding layer 130 provides for a more reliable or good adhesion interface between the Ge layer 131 of wafer bonding layer 130 and the substrate surface of wafer 120.

As can be seen, following eutectic bonding, the bonding layer 131, such as the Ge layer, forms eutectic bond with the Aluminum layer 140₁ of wafer 110, while the barrier layer 133 of wafer bonding layer 130 protects the substrate or Si surface of wafer 120 from reacting with the Ge layer 131 of wafer bonding layer 130. This process is therefore also very stable and requires much less control during the eutectic bonding process.

FIG. 2d shows yet another embodiment, in which the wafer bonding layer 130 includes a combined Ge layer 131 on a patterned Amorphous Silicon layer 235. As Amorphous Silicon layer is an insulator, it prevents electrical connections from being made through it. As such, via patterns may be formed on the Amorphous Silicon layer 235 to facilitate electrical connection between the Aluminum layer 140 on both wafers 110 and 120 through the Ge layer 131 of wafer bonding layer 130. In one embodiment, the via is patterned as the Amorphous Silicon layer 235 and Ge layer 131 are deposited on one of the wafer contact surface layers.

Wafers 110 and 120 in this embodiment include the same layers as shown in FIG. 2a. Therefore, as in FIG. 2a, while the wafer bonding layer 130 is formed on the Aluminum layer 140₂ of wafer 120, but it may be formed on the Aluminum layer 140₁ of wafer 110 in another embodiment. Referring to the right side of FIG. 2d, a conductive via contact 212 is formed following the eutectic bonding of wafer 110 and 120 via the diffusion of the Ge layer 131 of wafer bonding layer 130 with the Aluminum layer 140 of wafers 110 and 120. The via contact 212 provides electrical connection between the first and second wafers. Further, this process is also very stable and does not require much control during the process as the Amorphous Silicon controls the diffusion of Ge on Aluminum layer 140₂.

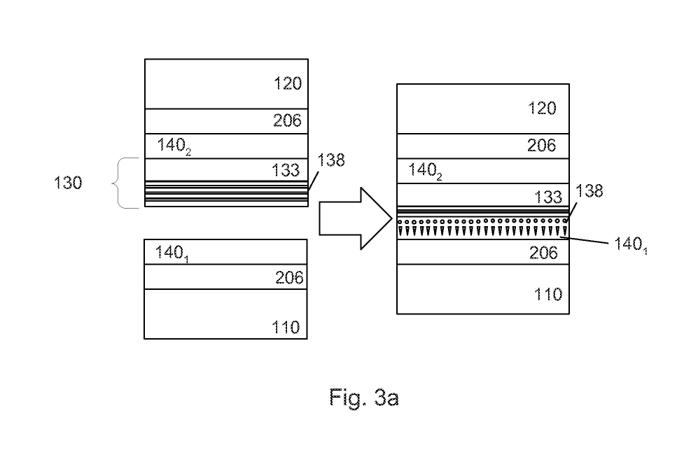

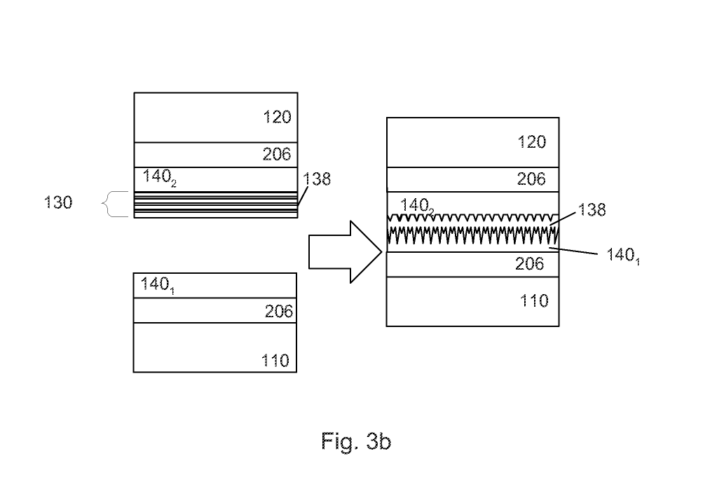

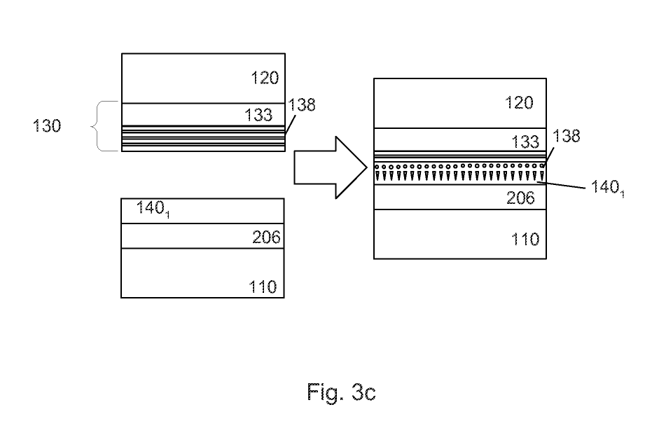

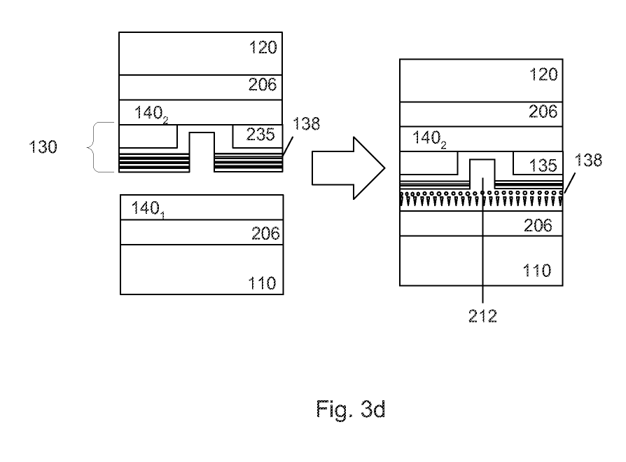

FIGS. 3a-3d show cross-section views of other embodiments of the wafer bonding layer 130 in a eutectic bonding process which may be applied in any of the wafer assemblies as described in FIGS. 1a-1c. FIGS. 3a-3d are similar to FIGS. 2a-2d except that the bonding layer which includes a single CMOS foundry compatible material is replaced by a CMOS foundry compatible material stack. For example, the Ge layer 131 of wafer bonding layer 130 is replaced by a Ge/Al multilayer 138 to facilitate more homogeneous diffusion between wafer bonding layer 130 and the Aluminum layer 140 of wafers 110 and 120. thereby resulting in a more reliable bond. As shown, the Ge/Al multilayer 138 may include a series of thinner Ge layers that is interspersed in an alternating manner with a series of thinner Al layers.

FIG. 3a shows the use of a wafer bonding layer 130 in a bonding process that requires a lot of electrical connections to be made between the wafers to be bonded. As shown on the left side of the FIG. 3a, first and second wafers 110 and 120 are provided. The first and second wafers, in one embodiment, are different types of wafer. In one embodiment, the first wafer 110 is a MEMS wafer while the second wafer 120 is a CMOS cap wafer. Other suitable types of wafers may also be useful. In other embodiments, the first and second wafers are of the same type. The first and second wafers 110 and 120 each having a dielectric layer 206 formed in between the wafers 110 and 120 and contact surface layers 140₁ and 140₂. The contact surface layers 140₁ and 140₂, for example, include Aluminum layer. Other suitable types of conductive surface layers may also be useful.

A wafer bonding layer 130, as shown in FIG. 3a, includes a CMOS foundry compatible material stack 138 which forms eutectic bond with the contact surface material and a barrier layer 133 which may be deposited on either wafer 110 or wafer 120. Wafer bonding layer 130 may be deposited on any aluminum surface of wafer 110/120. In one embodiment, the CMOS foundry compatible material stack 138 includes a Ge/Al multilayer 138 and the barrier layer 133 is a diffusion barrier layer which is the same as that already described in FIG. 2a above. Other suitable materials may also be used to form the CMOS foundry compatible material stack. As shown in FIG. 3a, wafer bonding layer 130 is firmed on the Aluminum layer 140₂ of wafer 120, but it may be formed on the Aluminum layer 140₁ of wafer 110 in another embodiment.

The right side of FIG. 3a shows wafer bonding layer 130 following the formation of a eutectic bond between wafer 110 and wafer 120. As can be seen, the Ge/Al multilayer 138 of wafer bonding layer 130 facilitates bonding with the Aluminum layer 140₁ of wafer 110, while the barrier layer 133 of wafer bonding layer 130 protects the Aluminum layer 140₂ of wafer 120 from reacting with the Ge/Al multilayer of wafer bonding layer 130. As can be seen, Ge/Al multilayer 138 first inter-diffuse homogenously before diffusing into the Aluminum layer 140₁ of wafer 110. This process is therefore very stable and does not require much control during the eutectic bonding process. The wafer bonding layer 130 bonds the first and second wafers. In the case where the first and second wafers are active wafers, the wafer bonding layer 130 also provides electrical connection between the first and second active wafers as the wafer bonding layer includes the bonding and barrier layers which are both conductive.

FIG. 3b shows an alternative embodiment, in which the wafer bonding layer 130 includes the Ge/Al multilayer 138, but wafers 110 and 120 have the same layers as that shown in FIG. 3a. As such, common elements may not be described or described in detail. As shown in 3b, wafer bonding layer 130 is formed on the Aluminum layer 140₂ of wafer 120, but it may be formed on the Aluminum layer 140₁ of wafer 110 in another embodiment, similar to that described in FIG. 2b. For example, for the process as shown in FIG. 2b, where wafer bonding layer 130 includes a single Ge layer 131; the process parameters of the eutectic bonding process have to be controlled very carefully to ensure even diffusion of the Ge layer 131 into the Aluminum layer 140 of wafers 110 and 120.

In contrast, the process as shown in FIG. 3b, which shows the use of a Ge/Al multilayer 138, does not require much control in the eutectic bonding process to ensure even diffusion of the Ge/Al multilayer 138 into the Aluminum layers of wafers 110 and 120, thereby saving time and manpower, which in turn reduces cost. As can be seen, the Ge/Al multilayer 138 first inter-diffuses homogenously before diffusing into aluminum layers 140 of wafers 110 and 120. This allows for better control of interconnect metallization.

FIG. 3c shows yet another embodiment of the wafer bonding layer 130 in a eutectic bonding process which is similar to that described in FIGS. 3a and 3b. As such, common elements may not be described or described in detail. Referring to FIG. 3c, the wafer bonding layer 130 includes the Ge/Al multilayer 138 and a barrier layer 133. This embodiment shows a bonding process where not many electrical connections are made between the two wafers being bonded together. As such, while wafer 110 has the same layers as that shown in FIG. 3a, wafer 120 may include only the wafer substrate layer.

The wafer substrate preferably includes silicon. It is understood that other suitable types of wafer substrate materials, such as but not limited to glass, silicon-on-insulator (SOI), GaAs or GaN, may also be useful. In this case, the wafer bonding layer 130 may be directly deposited on the wafer substrate surface of wafer 120 as the diffusion barrier layer 133 in wafer bonding layer 130 provides for a more reliable or good adhesion interface between the Ge/Al multilayer 138 of wafer bonding layer 130 and the substrate surface of wafer 120.

As can be seen, following eutectic bonding, the Ge/Al multilayer 138 of wafer bonding layer 130 facilitates bonding with the Aluminum layer 140₁ of wafer 110, while the barrier layer 133 of wafer bonding layer 130 protects the substrate or Si surface of wafer 120 from reacting with the Ge/Al multilayer 131 of wafer bonding layer 130. This process is therefore also very stable and does not require much control during the eutectic bonding process. As shown, the Ge/Al multilayer 138 first inter-diffuses homogenously before diffusing into aluminum layers 140 of wafers 110 and 120. This allows fur better control of interconnect metallization.

FIG. 3d shows yet another embodiment, in which the wafer bonding layer 130 includes a combined Ge/Al multilayer 138 and a patterned Amorphous Silicon layer 235. As Amorphous Silicon layer is an insulator, it prevents electrical connections from being made through it. As such, via patterns may be formed on the Amorphous Silicon layer 235 to facilitate electrical connection between the Aluminum layer 140 on both wafers 110 and 120 through the Ge/Al multilayer 138 of wafer bonding layer 130.

Wafers 110 and 120 in this embodiment include the same layers as shown in FIG. 3a. Therefore, as in FIG. 3a, while the wafer bonding layer 130 is formed on the Aluminum layer 140₂ of wafer 120, but it may be formed on the Aluminum layer 140₁ of wafer 110 in another embodiment. Referring to the right side of FIG. 3d, a conductive via contact 212 is formed following the eutectic bonding of wafer 110 and 120 via the diffusion of the Ge/Al multilayer 138 of wafer bonding layer 130 with the Aluminum layer 140 of wafers 110 and 120. This process is also very stable and does not require much control during the process.

In all of the embodiments described above, wafer bonding layer 130 may be deposited as part of the processing recipe of a CMOS compatible process, thereby improving throughput of the processing process. In one embodiment, the bonding and barrier layers of the wafer bonding layer, such as Ge, Ti and Ta layers, for example, are formed using evaporation or sputtering techniques. In a other embodiment, the Amorphous Silicon layer of the wafer bonding layer is formed using plasma chemical vapor deposition technique. Other suitable types of techniques may also be employed to form wafer bonding layer 130. In one embodiment, wafer bonding layer 130 may have a thickness of about 0.3-0.9 μm. Other suitable thickness ranges for the wafer bonding layer may also be useful. Where the wafer bonding layer 130 includes a combination of a Ge layer 131 on a barrier layer 133, the thickness of the Ge layer 131 is preferably about 0.2-0.6 μm and the thickness of the barrier layer 133 is preferably about 0.1-0.3 μm. Other suitable thickness ranges for the Ge and barrier layers may also be useful.

Where the wafer bonding layer 130 includes a combination of a Ge layer 131 on an Amorphous Silicon layer 235, the thickness of the Ge layer 131 is preferably about 0.2-0.6 μm and the thickness of the Amorphous Silicon layer 235 is preferably about 0.2-1.0 μm. Other suitable thickness ranges for the Ge and Amorphous Silicon layers may also be useful. Where the wafer bonding layer 130 includes a Ge/Al multiplayer 138, the thinner Ge and Al layers are each about 0.1-0.2 μm. Other suitable thicknesses may also be useful provided the thickness of the Ge layer(s) is chosen so that a good eutectic bond with the Aluminum layer 140 on the wafers can be achieved.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A wafer bonding process comprising:
providing a first wafer,
providing a second wafer; and
providing a wafer bonding layer, wherein the wafer bonding layer is provided separately on a contact surface layer of the first or second wafer as part of a CMOS compatible processing recipe.

2. The wafer bonding process of claim 1 wherein the wafer bonding layer is provided on the contact surface layer of the second wafer and the contact surface layer of the first wafer is an Aluminum layer.

3. The wafer bonding process of claim 1 wherein the wafer bonding layer comprises a bonding layer which is a CMOS foundry compatible material which forms a eutectic bond with an Aluminum contact surface layer of the first or second wafer.

4. The wafer bonding process of claim 1 wherein the wafer bonding layer comprises at least a Ge layer.

5. The wafer bonding process of claim 1 wherein the wafer bonding layer comprises a Ge layer and a barrier layer.

6. The wafer bonding process of claim 5 wherein the barrier layer comprises Ti, TiN, Ta, TaN or alloys thereof.

7. The wafer bonding process of claim 5 wherein the Ge layer has a thickness of about 0.2-0.6 μm and barrier layer is preferably about 0.1-0.3 μm.

8. The wafer bonding process of claim 1 wherein the first and second wafers comprise wafers of the same type.

9. The wafer bonding process of claim 1 wherein the first and second wafers comprise a CMOS wafer.

10. The wafer bonding process of claim 1 wherein the first wafer comprises a CMOS wafer and the second wafer comprise a MEMS wafer.

11. A wafer bonding layer comprising:
a Ge layer over a barrier layer, wherein the harrier layer may be an electrical conductor or an electrical insulator.

12. The wafer bonding layer of claim 11 wherein the barrier layer is an electrical conductor and comprises Ti, TiN, Ta, TaN or alloys thereof and has a thickness of about 0.1-0.3 μm.

13. The wafer bonding layer of claim 11 wherein the barrier layer is an electrical insulator comprising amorphous silicon having a thickness of about 0.2-1.0 μm.

14. The wafer bonding layer of claim 11 wherein the Ge layer comprises a Ge/Al multilayer that includes a series of thinner Ge layers that is interspersed in an alternating manner with a series of thinner Al layers.

15. The wafer bonding layer claim 14 wherein the thinner Ge and Al layers each having a thickness of about 0.1-0.2 μm.

16. A wafer bonding process comprising:
providing a first wafer,
providing a second wafer; and
providing a wafer bonding layer, wherein the wafer bonding layer is provided separately on a contact surface layer of the first or second wafer as part of a CMOS compatible processing recipe, wherein the contact surface layer of the other wafer is an Aluminum layer.

17. The wafer bonding process of claim 16 wherein the wafer bonding layer comprises a Ge/Al multilayer that includes a series of thinner Ge layers that is interspersed in an alternating manner with a series of thinner Al layers.

18. The wafer bonding process of claim 17 wherein the wafer bonding layer comprises the Ge/Al multilayer and a barrier layer.

19. The wafer bonding process of claim 17 wherein the wafer bonding layer comprises the Ge/Al multilayer and an amorphous silicon layer.

20. The wafer bonding process of claim 17 wherein the first wafer comprises a CMOS wafer and the second wafer comprise a MEMS wafer.
